(19) United States
(12) Patent Application Publication
(10) Pub. No.: US 2021/0314073 A1
(43) Pub. Date: Oct. 7, 2021

(54) MACHINE LEARNING AND DATA ANALYSIS FOR RF TESTING AND OTHER HARDWARE TESTING

(71) Applicant: Ying Wang, Herndon, VA (US)

(72) Inventor: Ying Wang, Herndon, VA (US)

(21) Appl. No.: 16/231,920

(22) Filed: Dec. 24, 2018

Related U.S. Application Data
(60) Provisional application No. 62/576,672, filed on Oct. 25, 2017.

(51) Int. Cl. H04B 17/00; H04B 17/29; H04B 17/19; G01R 31/28; G06K 9/62; G06N 20/00

(52) U.S. Cl. CPC H04B 17/0085; H04B 17/29; G06N 20/00; G01R 31/2822; G06K 9/6256; H04B 17/19

(57) ABSTRACT

The implementation of “Machine learning and data analysis for RF testing and other hardware testing” can detect and discover RF test failures by analyzing data from RF calibration station. It can dramatically reduce production cost, optimize production line management, reduce field return cost, improve product quality, and increase precision and accuracy of RF stations on production line. Furthermore, this system providers reference for optimizing hardware configure, improve RF design, and discover indirect potential RF issues. At last, it provides a more thorough understanding of the multi-dimensional RF limits system. With the data collected and analyzed after rolling the system to the production line can be used to deliver a more comprehensive spec for better RF quality. This invention is not limited to cellular stations, but also applies to Bluetooth, WiFi, NFC and other RF stations. This system can also be extended to hardware testing stations other than RF stations with some adjustment.

The present applications claims priority to the earlier filed provisional application having Ser. No. 62/576,672, and hereby incorporates subject matter of the provisional application in its entirety.”

### BACKGROUND

RF calibration and testing are one of the most important part in any mobile and wireless device production. For the same design, the variation among each unit on the production line can't be neglected. Without correct calibration, especially in cellular components, there is high probability that the device will fail specs and standards. The cost of RF calibration and testing, including units per hour at each station, test time, instrument cost etc. contribute significantly on the over production cost. Passing RF test items defined in the specs is mandatory for FCC's approval of wireless and mobile devices. Thus, reducing test time and increase accuracy are the keys for a successful wireless product. R&D department, testing and validation department and operations department in wireless product companies put a lot of efforts and work on reducing the test time, increasing yield, and reducing retest and approaching high accuracy. Even with the current high standard production line calibration and testing, units may still fail in the field, and generate a high return cost.

### BRIEF SUMMARY OF THE INVENTION

One application of this invention is to predict the test failures at the state of calibration by machine learning method to train data samples that passed all the test items in specs and data samples that failed in certain test items in specs. In most production line, especially for cellular technology, there are two stations, one is calibration station, which writes data into the units; another one is test station, which runs the test items in the spec on the units that have the said calibration data written in. This prediction can eliminate the necessity of test station and reduce the test time and cost on test station. An embodiment of the inventions can improve the accuracy of calibration by moving the limits to a higher standards and feedback to the system to modify calibration data written to the units. Even in the situation a very rarely failures, this invention is able to make accurate prediction. An application of the system combines unsupervised learning with supervised learning and is able to detect hardware potential issues that not yet defined by specs and standards defined by FCC and other orginization.

An embodiment of the inventions can set up a different way of viewing RF calibration and test. It views calibration data as an entirety and setup a connection with calibration and test. It combines RF design and testing domain knowledge with machine learning and designed a unique system and opens a new approach for RF design and testing. It saves production cost significantly. It increases the accuracy of RF design and testing that traditional hardware analysis cannot reach.

### BRIEF DESCRIPTION OF THE DRAWINGS

FIG. 1 is a diagram illustrating the position and benefit of applying systems described in this invention on a typical mobile device production line;

FIG. 2 is the overall flow graph illustrating the design of applying machine learning in RF system;

FIG. 3 is a diagram illustrating exemplary to illustrating the flow graph and process of the system in FIG. 1 and FIG. 2;

FIG. 4 is the plot illustrating training process of the said machine learning algorithm. Green dots represent the passing samples, yellow, red and blue dots represent samples different types of failings items.

FIG. 5 is the plot illustrating testing result using the said trained model in FIG. 4;

FIG. 6 is the plot illustrating the “forced weight adjustment” component in the training process for balancing precision and recall;

FIG. 7 is the illustration the “passed units classification” component in the training process for uncommon or rare failure types.

FIG. 8, 9, 10 are diagram illustrating a feedback design for hardware configuration selection and evaluation system.

FIG. 11 is a diagram illustrating the architecture of the entire system.

### DETAILED DESCRIPTION OF PREFERRED EMBODIMENTS

The following detailed description refers to the accompanying drawings. The same reference numbers in different drawings may identify the same or similar elements.

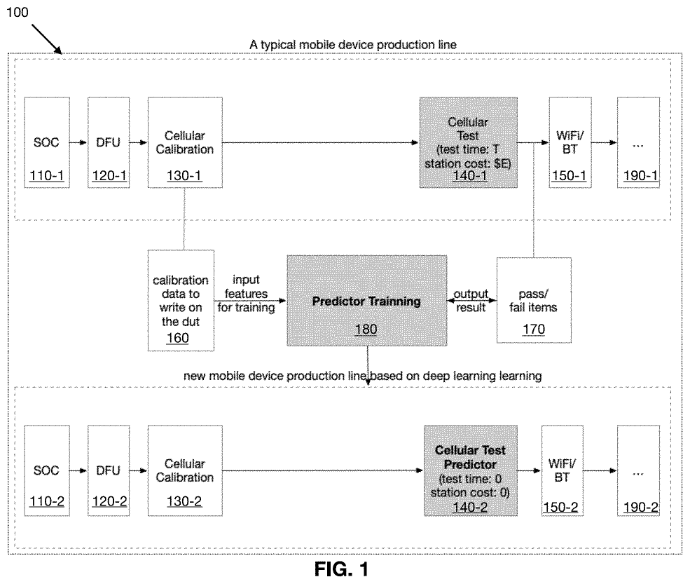

FIG. 1 shows the position and benefit of this invention implemented on a typical mobile device production line. For cellular production line, cellular chipset, other chipset, power amplifier, antenna switch, etc. are all integrated together. Each unit has a different RF character. Without a thorough RF calibration, the device will not meet FCC standards. RF Calibration and RF test are the twins in a production line. After the calibration, test will be performed to evaluate the calibration effects. From RF point of view, the same calibration procedure can't guarantee the same performance on each unit, and the variance on the performance is the reason that test station is inevitable. The cost to set up the station, maintain the station and running the station increase overall cost of the product significantly. However, FIG. 1 targets this issue. By learning from calibration data and the result on test station on history data or a small sample of all units using machine learning algorithms, FIG. 1 is able to reveal the relationship between calibration and test, and provide an innovated way of redesign the production line to be more accurate, to save time and cost by eliminating test stations.

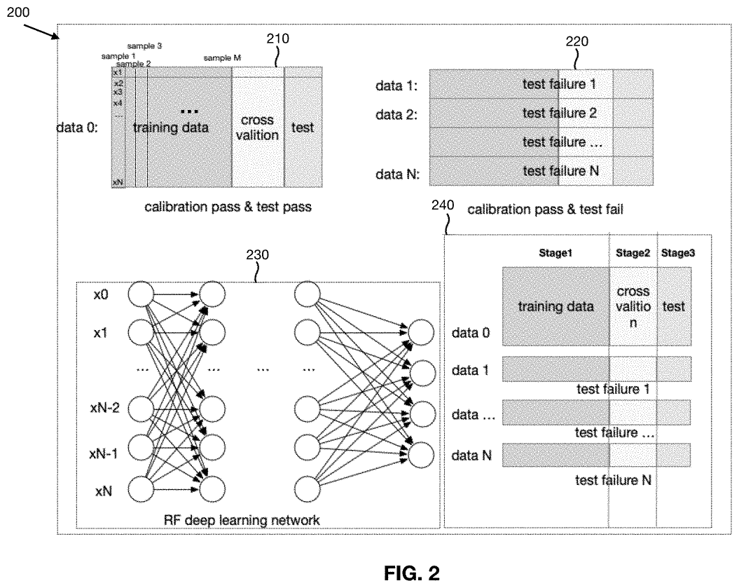

FIG. 2 illustrates the overall flow graph of the design of the machine learning for RF testing. Based on training data, we labeled all the data from units that passed calibration stations in 210 and 220. Data that passed at test station is in 210. Data that failed at test station is in 220. System initially runs in 3 stages, training stage, cross validation stage and test stage. Based on the data scale, typical percentages of data in these three stages are (60%, 20%, 20%) or (98%, 1%, 1%). Cross validation is to evaluate the number of layers, number of nodes each layer, and other parameters to get the most optimized training results. The testing data is to evaluate the precision rate and recall rate of the prediction result. These 2 rates, combine with field return cost will be used to determine whether there is enough data to provide confidence to eliminate RF test stations.

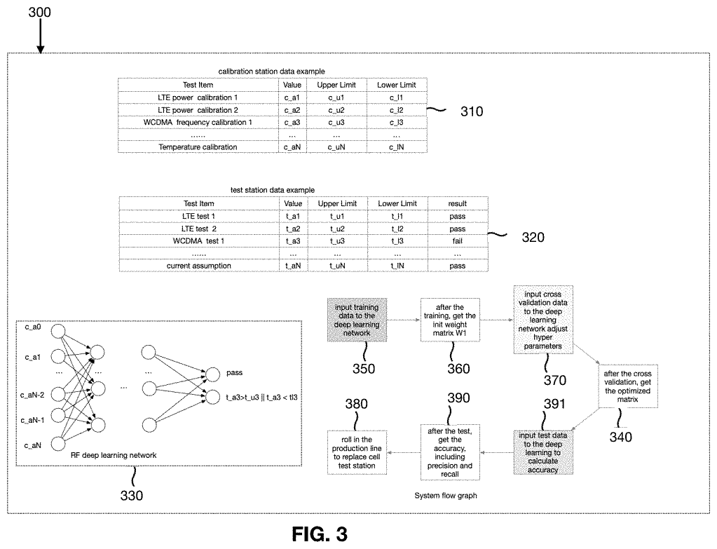

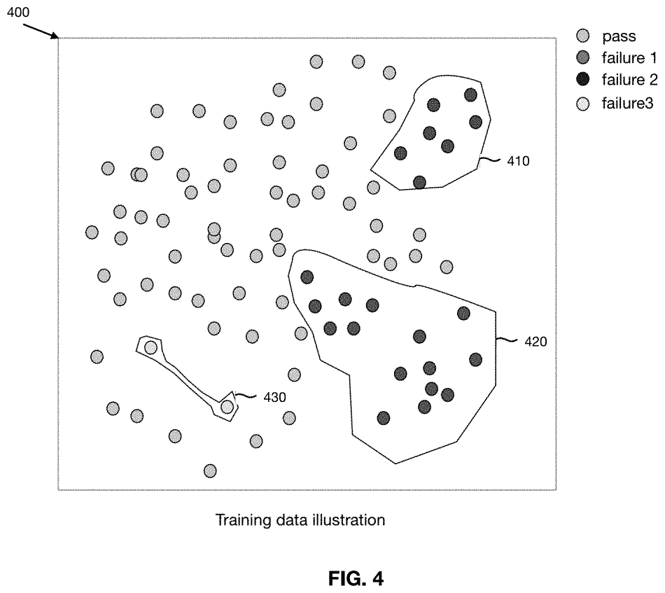

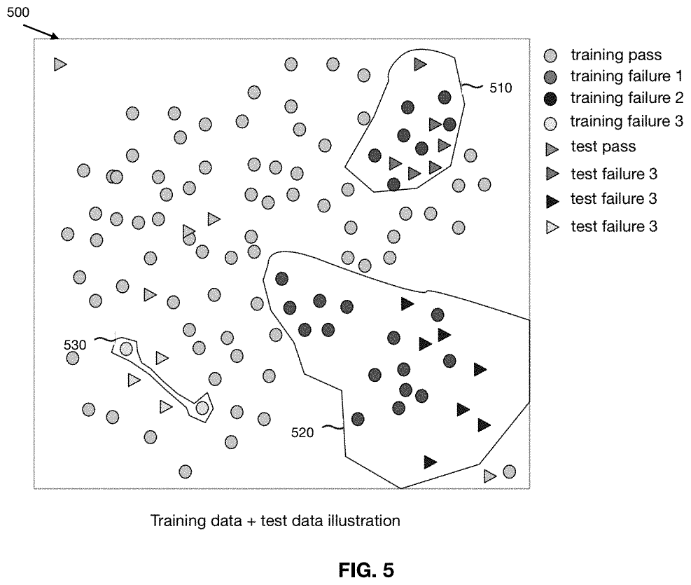

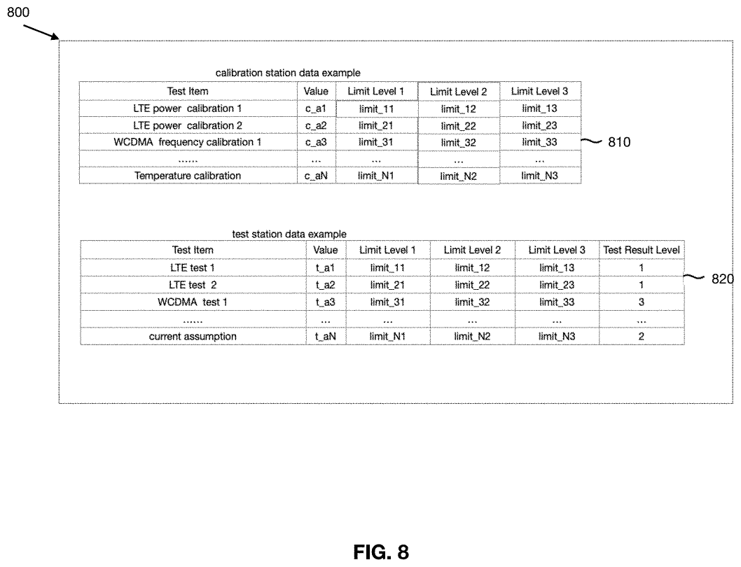

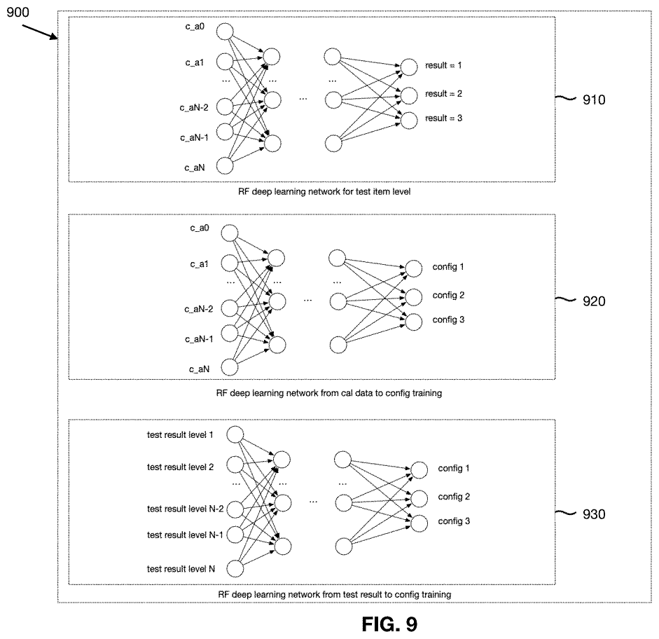

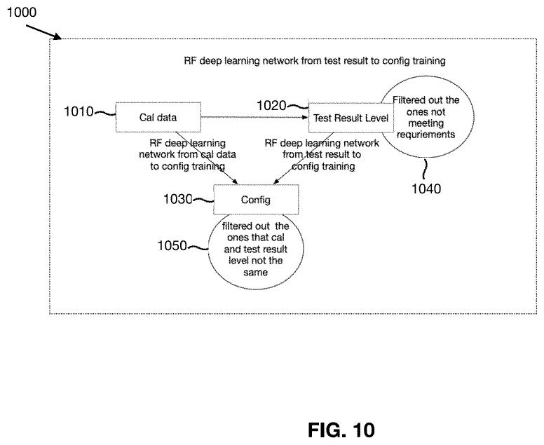

FIG. 3 is an example to explain the flow and process of the system. The example illustrates the single error situation. After training stage, we are able to get the initial weight matrix to predict the result. During cross validation, we adjust the learning rate and other hyperparameters to have an optimized weight matrix. At the test stage, we get the evaluation of the system through precision rate and recall rate. The precision rate represents the ratio of true positive versus the number of predicted positive, in our case, positive means the failures on test station. The recall rate represents the ratio of true positive versus the actual positive. Consider the cost of inaccuracy on each of the two cases, recall rate need to be controlled stricter. In most of production line operation, recall rate should be less than 10 e-5. This means that in the worst case, there is 10 e-5 probability that an actual failed unit will be ignored. If we use a common 0.5% failure rate on test station, that will result in a 5*10-7 recall rate, which is less or equal to the issues caused by the measurement inaccuracy in the current production line. There are two extensions of this system that need to be considered. One of the two cases is illustrated in FIG. 4-7 and the other is illustrated in FIG. 8-10. Both two cases are about the situation when limited number of samples that failed for a specific failure.

FIG. 4-FIG. 7. For the system in FIG. 3, given enough data, all the error can be detected. There are two things that need to be addressed to implement this system on the production line. One is the balance between precision and recall, and the other is uncommon failures. Lower precision and recall rate increase the overall cost of a unit. For each precision error, the cost added is the cost of having one unit to be tested on test station. For each recall error, the cost added might be a filed return. Compared to recall error cost, the cost of precision error is lower. Our goal is to reduce recall error as much as possible, while controlling precision error at a reasonable rate.

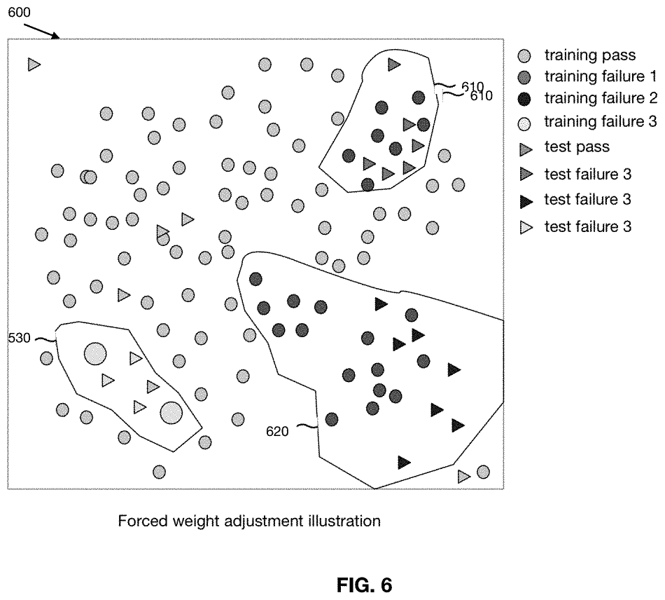

There is higher probability that recall error happened on uncommon failures. For the failures that has a very small failure rate, some of them are important errors to catch. In a lot of cases in engineer, small possibility reveals big issues. As described in “Forced Weight Adjustment illustration” in FIG. 6, by adjust the weight, we are forcing the boundary between passing results and uncommon failures towards the direction of passing results to reduce recall errors. Data shows this method is very effective.

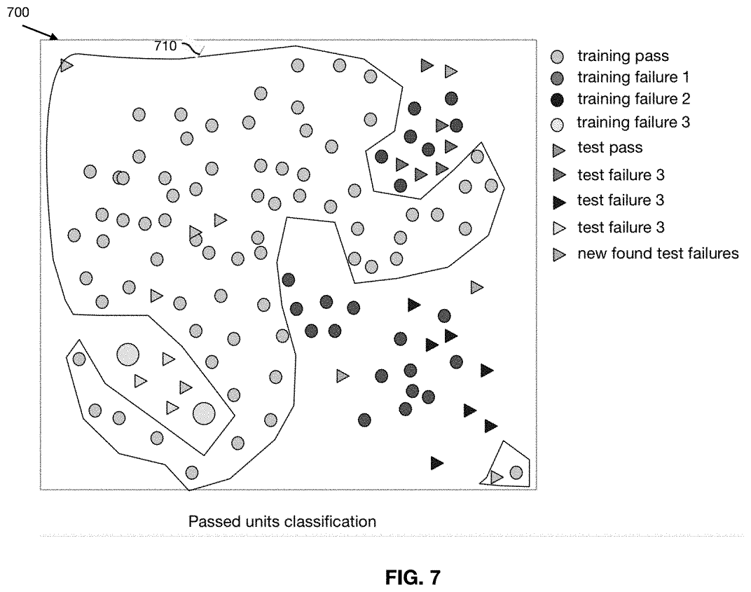

In FIG. 7, we eventually push the boundaries to only isolate passed units, which means to abstract the features of passed units instead of all the different failures. This is illustrated in FIG. 7: “passed units classification”. In this case, even a failure only appear in testing data set, not in training data set, as the purple triangles, the recall error will not appear because the classification can tell that they are not passed units. This increase the prediction accuracy significantly and requirement for the number of training samples dropped significantly as well.

FIG. 8-FIG. 10. Accuracy and performance of RF production line is determined by partially by calibration system, and partially by hardware configuration. Because of supply chain or other consideration, sometimes a tradeoff between hardware configuration and performance need to be made. In order to meet certain requirements, we need to know which hardware configuration are acceptable. In FIG. 8-FIG. 10, we have invented a feedback system for hardware configuration selection and evaluation system. The steps are as follows:

1. Train all three networks RF deep learning network for test item level, RF deep learning network from calibration data to config training 1010, and RF deep learning network from test result to config training 1020.

2. Filter the data that doesn't meet certain RF requirements from the first network 1040.

3. For the remaining data, only keep the ones that network 2 and network 3 pointed to the same config 1030, 1050

These remains configurations combinations are the one that will meet the requirements from the specs and standards and used in the production line.

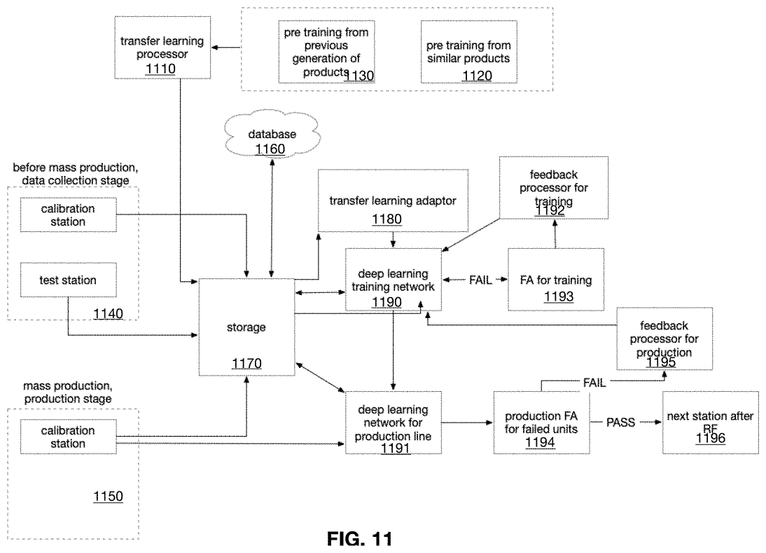

FIG. 11 is the system architecture of the entire system. During the training stage, data from calibration and test station are ported to database through storage 1170 component 1140. The system 1190 fetches data from database through storage. The data that doesn't pass the test portion will go through Failure Analysis 1193 for training component and the processed result will be feedback to the network. The output of the deep learning training network will feed into the deep learning network for production line component 1191. During test stage, there is no test data because test station is eliminated 1150. Data from calibration will be feed into deep learning network 1190 for production line component as part of the production line. Note that the component for production FA for failed units 1194 are used for process the ones that the result is FAIL in the deep learning network for production line. However, the FA for training component 1193 is used for processing data that results are different with real test station data.

Similar to experienced engineers learning from previous products, this system have the ability to intelligently learn from previous products, similar products or earlier builds of the same products. Previous products, similar products or earlier builds of the same products training results 1130 are feed into the database through storage after transfer learning processor 1110. Deep learning training network will fetch relative data from storage through transfer learning adaptor. Using the new transfer learning algorithm, the system approaches a higher accuracy and efficiency.

Within the product's own build cycle, the system will learn from its previous experience and adapt to new changes in the production line. The system not only saves cost but also approaches higher accuracy. In the production line, it is very common to use AAB test, which means that if a unit fails, it will be tested on the same fixture one more time and if it still failed, it will be tested on another fixture of the same station one more time. If either of these two time passes, the unit is considered retest pass. The issue of retest pass has two impacts, one is retest rate increases overall retest time, the other is that it may have potential issues that hide behind the retest rate. In the system of FIG. 11, the test station retest items are also labeled and hence detected by the deep learning training network component in the calibration stage. There is a clear pattern for most of the retest times in the calibration stage.

The embodiment of this invention can be used for replacing RF test station in the production line with a higher accuracy and higher efficiency. It saves the cost of the entire RF test station, including the cost to setup the line, and the cost to operate the line. It increases the accuracy by removing station variation, learning from previous products, detecting retest items, and reevaluating limits. It provides a learning model to benefit future products.

Deep learning training network can be used in this system as the training model. This model detects the pattern of different units and categorizes them by test station results. This model detects the failures that would happen in test station at calibration stage without running additional test.

For failure that appear less frequently, the “Forced Weight Adjustment” component included in the deep learning training network is able to force a larger margin in the multi-dimensional space of the failed samples, to be able to detect future failures.

As a further implementation of [0025], we are able to abstract the features or patterns of a good units. In this way, any units that fell outside the range of a good unit will be detected. Even there are failures only appears in the test data set but not in the training data set, the system is able to accurately detect it.

The ability to learn from history provides more accuracy and efficiency. The transfer learning component is able to abstract the features from history or similar products. Besides accuracy and efficiency, this is also useful to detect the trend of the different product generations and benefit for future research and development.

One embodiment of this invention is the first time to unveil the multi-dimensional RF calibration and test based on the current spec and data from the production line. It targets the relationship of different RF parameters from a data analysis angle instead of hardware analysis angle. This approach reaches a much higher accuracy in many aspects than purely RF hardware analysis.

The detected relationship between the calibration and test can not only used for detecting failed units without testing them, but also extract features for engineers for better design in the future development. It detects the patterns that showed up when large amount of units' data are collected. It discovers RF connections and performance that can't be directly explained by RF theory.

One embodiment of this invention is to detect retest units. When reviewing data from RF test station, certain test items may show a high retest rate. A common diagnosis of retest items is fixture accuracy. However, calibration data of these units show a strong detectable pattern. By using this detection, we are able to detect retest issues that have a potential to affect product quality.

The trend for current consumer mobile devices is getting more and more compact with an increasing number of components in a smaller space. When the demanding for parts supply is large, the same parts will need to come from different vendors. The multiple supply vendors of parts will also add difficulties on keeping the consistent performance across all units. By analyzing the feedback in the system as in FIG. 10, we are able to qualifying hardware configuration based on the performance of RF performance. For example, in some scenario, the power accuracy is more important for the product design, and in some other scenario, EVM accuracy is more important. The system in FIG. 10 is able to calculate the RF performance for hardware configurations.

One embodiment of this invention detects the failures in a multi-dimensional way, and provides a more comprehensive limits system for the units compared to current IEEE spec. For example, max power and ACLR on WCDMA always have a strong correlation. For a unit that passes both max power limit and ACLR limit, but has an abnormal correlation between these two test items will show a problem in the field. By collecting data and the analyzing them in this system, a new spec with more comprehensive limit system can be delivered to replace current IEEE spec.

This invention is not limited to cellular stations, but also applies to Bluetooth, WiFi, NFC and other RF stations. It can dramatically save cost and increase accuracy on the production line. This system can also be extended to stations other than RF stations with some adjustment.
The present applications claims priority to the earlier filed provisional application having Ser. No. 62/576,672, and hereby incorporates subject matter of the provisional application in its entirety.

What is claimed is:

1. A method comprising:
analyzing, at a computer, the data used for writing into the unit and the data from other units generated previously
determine, at a computer, that the said unit can pass or fail any test item in specs or standards whereby said analysis result can be used to determine the said unit pass or fail.

2. The method of claim 1, wherein the analysis includes one or more of machine learning method, deep learning method, unsupervised learning, supervised learning method, other data analysis and data mining method.

3. The method of claim 1, wherein specs or standards includes one or many of IEEE spec, 802.11 spec, Blue booth spec that regulated in Unite States or other countries in the world.

4. The method of claim 1, where in mobile devices includes one or many of cellular phone, devices that have WiFi or Blue Tooth functions, and devices with other wireless communication functions.

5. The method of claim 1, wherein the analysis uses one or more of the models to detect the pattern data of units and categorizes types of units by test station results.

6. The method of claim 1, where the said data from other units generated previously are training data set.

7. The method of claim 1, where the said learning of data is training the model to learn from training data set.

8. The method of claim 1, where the said data from data written into the units are the input of the test data set.
The method of claim 1, where the said determined unit can pass or fail any test item in specs or standards is the output of the test data set.

9. A method comprising:
learning, through machine learning or data analysis methods, from data generated from previous generated data,
replacing the RF test station or test items on production line in manufacturing
whereby said replacing the station can reduce cost.

10. The method of claim 6, wherein the data can be generated from previous builds, previous version of the same product, or other products that has some similarities to the said product.

11. The method of claim 6, wherein the cost reduced includes one or more of the costs to setup the line and the cost to operate the line.

12. The method of claim 6, wherein the data is called training data in this invention.

13. The method of claim 9, wherein the training data are categorized based on their failed items in any single test based on the said spec or said standards

14. The method of claim 10, wherein the category has relatively few numbers of samples, a “Forced Weight Adjustment (FIG. 6)” component included in the deep learning training network is able to force a larger margin in the multi-dimensional space of the said data samples,
whereby to detect the failures more accurately.

15. The method of claim 10, wherein the categories, one embodiment is two type of categories, pass category and fail category. The categorizing comprising:
abstract the common features of a pass units
detect any units that fell outside the range of a pass unit and categorize said units as failed units
whereby, the categories have relatively few numbers of samples or no units with
new failures that not included in the said training data can be detected by the system.

16. The method of claim 1, wherein the analysis includes an embodiment of deep learning model.

17. A method comprising:
learning, through machine learning or data analysis methods, from data generated from previous generated data,
replacing the RF test station or test items on production line in manufacturing
whereby said the learning system increase the accuracy compared.

18. The method of claim 14, wherein the accuracy increased includes one or more of removing station variation, accumulating experience from previous products, detecting retest items, reevaluating limits, and providing information to benefit future products

19. The method of claim 14, wherein transfer learning component (610 in FIG. 6) is able to abstract the features from history or similar products. This is useful to detect the trend of the different product generations and benefit for future research and development.

20. A method comprising:
analyzing, at a computer, the data used for Radio Frequency (RF) calibration that is generated in the manufacturing process
determine, at a computer, that the mobile device tested inconsistent pass or fail on certain test item compared to the said specs or standards
whereby said RF calibration data analysis result can be used to detects retest pass/fail unit.

21. The method of claim 17, wherein some of the training data are categorized as retest pass/fail on certain test item based on multiple repeated test results on the said specs or standards

22. The method of claim 18, wherein the training data categorized as retest is used for analysis on retest detection through machine learning and other method.

23. A method comprising:
analyzing, at a computer, the data used for Radio Frequency (RF) calibration that is generated in the manufacturing process
combining, the information of hardware configuration of components on each unit
evaluating the expected overall said RF performance based on hardware configuration
qualifying a combination of hardware configuration to meet the requirements of RF performance.
whereby said performance information can be provided for hardware selection in mass production or other stages of the production.

24. A method comprising:
detecting the RF failures in a multi-dimensional way
providing a more comprehensive limits system for the units compared to current single test item-based specs and standards
whereby said a more comprehensive test of units.

25. A method comprising:
analyzing, at a computer or any processor, the data used to write into a test unit on the production line.
determine, at a computer or any processor, that the unit can pass or fail any test item defined in specs or standards without testing the said test items.
